(19) United States
(12) Patent Application Publication
(10) Pub. No.: US 2026/0056295 A1
(43) Pub. Date: Feb. 26, 2026

(54) LIDAR AND HEAT CONDUCTION DEVICE

(71) Applicant: AUTOX TECH PTE. LTD., SINGAPORE (SG)

(72) Inventors: Jianxiong Xiao, Shenzhen (CN); Qing Deng, Shenzhen (CN); Yizhou Shan, Shenzhen (CN); Gaowen Deng, Shenzhen (CN); Zhuo Li, Shenzhen (CN)

(73) Assignee: AUTOX TECH PTE. LTD., SINGAPORE (SG)

(21) Appl. No.: 19/214,405

(22) Filed: May 21, 2025

(30) Foreign Application Priority Data
Sep. 24, 2024 (CN) 2024223420092

(51) Int. Cl. G01S 7/481; H01S 5/024

(52) U.S. Cl. CPC G01S 7/4815; H01S 5/02469

(57) ABSTRACT

A thermal conduction device for a LiDAR includes an opto-mechanical bracket in contact with a heat dissipation component; a thermal conduction bracket spaced apart from the opto-mechanical bracket and in contact with the heat dissipation component; a plurality of circuit boards disposed at intervals and in parallel between the opto-mechanical bracket and the thermal conduction bracket, to accommodate a plurality of lasers, the plurality of lasers being arranged in a straight line at intervals along a placement direction of the circuit board; and a graphite sheet including a contact portion laid on a side of the circuit board away from the lasers; a first extension portion extending from the contact portion in a first direction to make contact with the opto-mechanical bracket; and a second extension portion extending from the contact portion in a second direction to make contact with the thermal conduction bracket. The disclosure further provides a LiDAR. DRAWINGS

### CROSS REFERENCE TO RELATED APPLICATION

This non-provisional patent application claims priority under 35 U.S.C. §119 from Chinese Patent Application No. 202422342009.2 filed on Sep. 24, 2024, the entire content of which is incorporated herein by reference.

### TECHNICAL FIELD

The disclosure relates to the field of LiDAR, particularly to a LiDAR and a heat conduction device for LiDAR.

### BACKGROUND

LiDAR, as one of the core sensors in autonomous driving systems, offers advantages such as long detection distance, high resolution, and the ability to operate around the clock. Increasing the number of lines in LiDAR can achieve denser point cloud resolution, thereby enabling precise perception of complex and dynamic driving environments. The conventional approach for achieving multi-line functionality in mechanical LiDAR is to arrange multiple lasers in both the vertical and horizontal directions on the plane of the optical lens. In the same space, the smaller the arrangement spacing between the lasers, the greater the number of lasers, resulting in more lines and higher angular resolution.

In existing technology, lasers require optical adjustment due to tolerances arising from the manufacture and assembly of the optical system. The uncertainty in the position of the lasers and their components makes it difficult to form a fixed heat conduction connection, and the close arrangement of multiple lasers further increases the difficulty of heat dissipation, making it challenging to conduct heat away from the lasers.

### SUMMARY

The disclosure provides a LiDAR and a heat conduction device for LiDAR to solve the problems of fixed heat conduction connection and heat dissipation.

In a first aspect, an opto-mechanical bracket, in contact with a heat dissipation component; a thermal conduction bracket, spaced apart from the opto-mechanical bracket and in contact with the heat dissipation component; a plurality of circuit boards, spaced apart and arranged in parallel between the opto-mechanical bracket and the thermal conduction bracket, each circuit board being configured to accommodate a plurality of lasers, the plurality of lasers being arranged in a straight line at intervals on one side of the circuit board, along a placement direction of the circuit board; and a graphite sheet, including: a contact portion, disposed on the side of the circuit board facing away from the lasers; a first extension portion, extending from the contact portion in a first direction to contact the opto-mechanical bracket; and a second extension portion, extending from the contact portion in a second direction to contact the thermal conduction bracket.

Further, the plurality of lasers are arranged away from the thermal conduction bracket.

Further, each the circuit board is provided with a mounting area near an edge, to accommodate the plurality of lasers.

Further, the circuit board is provided with thermal conduction holes, the thermal conduction holes extending from the side of the circuit board provided with the lasers to the side provided with the graphite sheet.

Further, the first direction extends along one end of the circuit board, and the second direction bends and extends from one side of the circuit board towards the thermal conduction bracket.

Further, the second extension portions of the graphite sheets corresponding to the respective circuit boards are stacked.

Further, the graphite sheet is a one-piece molded sheet.

Further, the LiDAR thermal conduction device further comprises a plurality of connecting pillars disposed between the opto-mechanical bracket and the thermal conduction bracket, the circuit board further being provided with a plurality of perforations, the connecting pillars passing through the perforations and being fixed at both ends to the opto-mechanical bracket and the thermal conduction bracket, respectively.

Further, the first extension portion and the second extension portion are provided with adhesive backing for adhering to the opto-mechanical bracket and the thermal conduction bracket, respectively.

In a second aspect, the disclosure also provides a LiDAR including: a plurality of lasers; and the aforementioned heat conduction device for LiDAR.

The disclosure employs a graphite sheet configured with: a contact section positioned on the non-laser side of the circuit board; a primary extension segment extending from the contact section in a first directional vector to establish contact with the opto-mechanical bracket; and a secondary extension segment extending from the contact section in a second directional vector to interface with the thermal conduction bracket. This tripartite configuration creates a continuous, low-resistance thermal pathway that ensures efficient heat transfer from the laser modules to the system's heat dissipation components, thereby maintaining optimal operating temperatures and enhancing device reliability.

### BRIEF DESCRIPTION OF THE DRAWINGS

To more clearly illustrate the technical solutions in the embodiments of the disclosure or in the prior art, the following provides a brief introduction to the drawings required for describing the embodiments or the prior art. It is apparent that the drawings described below are merely some embodiments of the disclosure. For those skilled in the art, other drawings can be obtained based on the structures shown in these drawings without exercising inventive effort.

FIG. 1 is an exploded view of a thermal conduction device for a LiDAR provided in an embodiment of the disclosure.

FIG. 2 is a partially exploded view of The thermal conduction device provided in an embodiment of the disclosure.

FIG. 3 is a schematic diagram of the stacking of graphite sheets in The thermal conduction device provided in an embodiment of the disclosure.

FIG. 4 is a schematic structural diagram of a LiDAR provided in an embodiment of the disclosure.

The Reference Numerals in the drawings are indicated as follows:

Thermal conduction device for LiDAR 1, Opto-mechanical bracket 10, Thermal conduction bracket 20, Circuit board 30, Perforation 301, Thermal hole 302, Mounting area 303, Connecting pillar 40, Graphite sheet 50, Contact portion 501, First extension portion 502, Second extension portion 503, Adhesive backing 504, Laser 60, Heat dissipation component 70, LiDAR 2.

The achievement of the objectives, functional features, and advantages of the disclosure will be further explained with reference to the embodiments and drawings.

### DETAILED DESCRIPTION OF THE EMBODIMENTS

In the description of the disclosure, it should be understood that the terms “length,” “width” “up,” “down,” “front,” “rear,” “left,” “right,” “vertical,” “horizontal,” “top,” “bottom,” “inner,” “outer,” and other similar terms indicating orientation or positional relationships are based on the orientation or positional relationships depicted in the accompanying drawings. These terms are solely for the purpose of facilitating the description of the disclosure and simplifying the description, and are not intended to indicate or imply that the devices or elements referred to must have specific orientations, be constructed or operated in specific orientations. Therefore, they should not be construed as limitations of the disclosure.

Furthermore, the terms “firs” and “second” are used solely for descriptive purposes and cannot be understood as indicating or implying relative importance or the number of technical features implied by the indication. Consequently, features qualified by “first” and “second” may explicitly or implicitly include one or more of such features. In the description of the disclosure, the term “plurality” means two or more, unless otherwise specifically and definitely limited.

In the disclosure, unless otherwise specifically defined and limited, terms such as “install,” “connect,” “link,” “fix,” and their derivatives should be broadly interpreted. For example, they may refer to fixed connections, detachable connections, or integration; mechanical connections or electrical connections; direct connections or indirect connections through intermediary media; internal communication between two elements or interaction between two elements. For those skilled in the art, the specific meanings of these terms in the context of the disclosure can be understood based on specific circumstances.

To provide a clearer and more accurate understanding of the content of the disclosure, a detailed description will now be provided in conjunction with the accompanying drawings. The drawings illustrate examples of embodiments of the disclosure, wherein identical numerals indicate identical elements. It should be understood that the proportions shown in the drawings are not to scale and are solely for illustrative purposes.

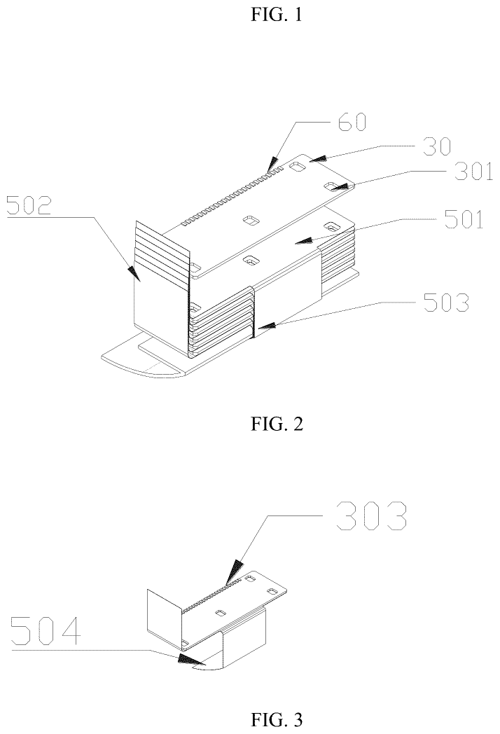

Referring to FIG. 1, a thermal conduction device 1 for a LiDAR 2 is illustrated. The LiDAR 2 includes a plurality of lasers 60 that emit laser light. The thermal conduction device 1 is configured to conduct heat generated by the lasers 60 during operation to the outside environment, thereby dissipating the heat generated by the lasers 60. The thermal conduction device 1 includes an opto-mechanical bracket 10, a thermal conduction bracket 20, a plurality of circuit boards 30, a plurality of connecting pillars 40, and a graphite sheet 50. Each circuit board 30 is equipped with a plurality of lasers 60. The circuit boards 30 are disposed between the opto-mechanical bracket 10 and the thermal conduction bracket 20, and the connecting pillars 40 connect the opto-mechanical bracket 10 and the thermal conduction bracket 20 while passing through the circuit boards 30 to fix the circuit boards 30 between the opto-mechanical bracket 10 and the thermal conduction bracket 20. The graphite sheet 50 is in contact with the circuit boards 30 to conduct heat generated by the lasers 60, thereby maintaining the circuit boards 30 within a preset temperature range.

The opto-mechanical bracket 10 is in contact with a heat dissipation component 70. The thermal conduction bracket 20 is spaced apart from the opto-mechanical bracket 10 and is in contact with the heat dissipation component 70.

Referring to FIGS. 1 and 2, where the circuit boards 30 are spaced apart and disposed in parallel between the opto-mechanical bracket 10 and the thermal conduction bracket 20. The connecting pillars 40 are disposed between the opto-mechanical bracket 10 and the thermal conduction bracket 20. The circuit boards 30 are equipped with a plurality of perforations 301 and a plurality of thermal holes 302, wherein the thermal holes 302 penetrate from the side of the circuit board 30 equipped with the lasers 60 to the side equipped with the graphite sheet 50. The connecting pillars 40 pass through the perforations 301 and are fixed at both ends to the opto-mechanical bracket 10 and the thermal conduction bracket 20, respectively. In this embodiment, the connecting pillars 40 are cylindrical, and the perforations 301 are circular, with the connecting pillars 40 and the perforations 301 being compatible. The connecting pillars 40 sequentially pass through the circuit boards 30 and the graphite sheet 50 to make contact with the thermal conduction bracket 20. The connecting pillars 40 and the perforations can also be other regular or irregular shapes, which can be set according to actual conditions and are not limited here.

Each circuit board 30 is configured to accommodate a plurality of lasers 60, with a mounting area 303 provided near the edge of the circuit board 30 for installing the plurality of lasers 60. In this embodiment, the plurality of lasers 60 are arranged in a straight line at intervals along the placement direction of the circuit board 30 on one side of the circuit board 30, with the plurality of lasers 60 facing away from the heat-conducting bracket 20. The position and arrangement of the aforementioned plurality of lasers 60 are merely examples and can be arranged according to actual conditions, without limitation herein.

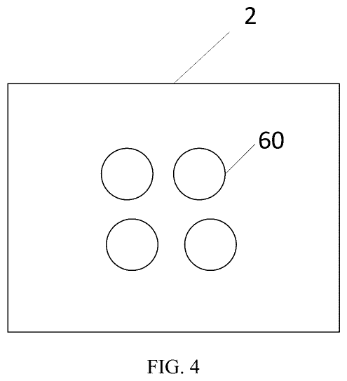

Referring to FIGS. 2 and 3, the graphite sheet 50 comprises a contact portion 501, a first extension portion 502, and a second extension portion 503. The contact portion 501 is laid on the side of the circuit board 30 facing away from the lasers 60. The first extension portion 502 extends from the contact portion 501 along a first direction to contact with the optical engine bracket 10. The second extension portion 503 extends from the contact portion 501 along a second direction to contact with the heat-conducting bracket 20. The graphite sheet 50 conducts heat along two directions, possessing high thermal conductivity in a plane, and requiring only a small thickness direction space to complete heat transfer, thereby solving the heat cascade issue caused by closely arranged multiple heat sources. The graphite sheet 50 is a thin sheet formed integrally and has a flexible structure, which can greatly facilitate optical alignment and avoid issues such as insufficient contact of conventional thermal interface materials.

In this embodiment, the first direction extends along one end of the circuit board 30, and the second direction bends and extends towards the heat-conducting bracket 20 along one side of the circuit board 30. The graphite sheet 50 forms thermal conduction paths on top and the sides of the circuit board 30, with a parallel design reducing the system's thermal resistance and improving temperature uniformity among the lasers, thus reducing later calibration and algorithm compensation costs. In this embodiment, the graphite sheet 50 is a thin sheet formed integrally. The second extension portions 503 of the graphite sheets 50 corresponding to respective circuit boards 30 are arranged in a stacked manner. The first extension portion 502 and the second extension portion 503 are provided with adhesive backing 504 for adhering to the optical engine bracket 10 and the heat-conducting bracket 20, respectively. The aforementioned use of adhesive backing 504 to fix the graphite sheet 50 to the optical engine bracket 10 and the heat-conducting bracket 20 can be replaced by other fixing tools according to actual conditions, without limitation herein.

Referring to FIG. 4, the LiDAR 2 includes a plurality of lasers 60 and a LiDAR heat-conducting device 1. The plurality of lasers 60 are installed on the LiDAR heat-conducting device 1. The structure of the LiDAR heat-conducting device 1 and the cooperation relationship between the plurality of lasers 60 and the LiDAR heat-conducting device 1 are described above and will not be repeated here.

It is apparent that those skilled in the art can make various modifications and variations to the disclosure without departing from the spirit and scope thereof. Thus, if these modifications and variations of the disclosure fall within the scope of the claims and their equivalents, the disclosure is also intended to include these modifications and variations.

The above-enumerated examples are merely preferred embodiments of the disclosure and cannot be used to limit the scope of the claims of the disclosure. Therefore, equivalent changes made according to the claims of the disclosure still fall within the scope covered by the disclosure.

1. A thermal conduction device for a LiDAR, comprising:
an opto-mechanical bracket, in contact with a heat dissipation component;
a thermal conduction bracket, spaced apart from the opto-mechanical bracket and in contact with the heat dissipation component;
a plurality of circuit boards, spaced apart and arranged in parallel between the opto-mechanical bracket and the thermal conduction bracket, each circuit board being configured to accommodate a plurality of lasers, the plurality of lasers being arranged in a straight line at intervals on one side of the circuit board, along a placement direction of the circuit board; and
a graphite sheet, comprising:
a contact portion, disposed on the side of the circuit board facing away from the lasers;
a first extension portion, extending from the contact portion in a first direction to contact the opto-mechanical bracket; and
a second extension portion, extending from the contact portion in a second direction to contact the thermal conduction bracket.

2. The thermal conduction device according to claim 1, wherein the plurality of lasers are arranged away from the thermal conduction bracket.

3. The thermal conduction device according to claim 2, wherein each the circuit board is provided with a mounting area near an edge, to accommodate the plurality of lasers.

4. The thermal conduction device according to claim 1, wherein the circuit board is provided with thermal conduction holes, the thermal conduction holes extending from the side of the circuit board provided with the lasers to the side provided with the graphite sheet.

5. The thermal conduction device according to claim 1, wherein the first direction extends along one end of the circuit board, and the second direction bends and extends from one side of the circuit board towards the thermal conduction bracket.

6. The thermal conduction device according to claim 5, wherein the second extension portions of the graphite sheets corresponding to the respective circuit boards are stacked.

7. The thermal conduction device according to claim 1, wherein the graphite sheet is a one-piece molded sheet.

8. The thermal conduction device according to claim 1, wherein the LiDAR thermal conduction device further comprises a plurality of connecting pillars disposed between the opto-mechanical bracket and the thermal conduction bracket, the circuit board further being provided with a plurality of perforations, the connecting pillars passing through the perforations and being fixed at both ends to the opto-mechanical bracket and the thermal conduction bracket, respectively.

9. The thermal conduction device according to claim 1, wherein the first extension portion and the second extension portion are provided with adhesive backing for adhering to the opto-mechanical bracket and the thermal conduction bracket, respectively.

10. A LiDAR, comprising:
a plurality of lasers; and
a thermal conduction device, comprising:
an opto-mechanical bracket, in contact with a heat dissipation component;
a thermal conduction bracket, spaced apart from the opto-mechanical bracket and in contact with the heat dissipation component;
a plurality of circuit boards, spaced apart and arranged in parallel between the opto-mechanical bracket and the thermal conduction bracket, each circuit board being configured to accommodate a plurality of lasers, the plurality of lasers being arranged in a straight line at intervals on one side of the circuit board, along a placement direction of the circuit board; and
a graphite sheet, comprising:
a contact portion, disposed on the side of the circuit board facing away from the lasers;
a first extension portion, extending from the contact portion in a first direction to contact the opto-mechanical bracket; and
a second extension portion, extending from the contact portion in a second direction to contact the thermal conduction bracket.

11. The LiDAR according to claim 10, wherein the plurality of lasers are arranged away from the thermal conduction bracket.

12. The LiDAR according to claim 11, wherein a mounting area is provided near an edge of each the circuit board, to accommodate the plurality of lasers.

13. The thermal conduction device according to claim 1, wherein the circuit board is provided with thermal conduction holes, the thermal conduction holes extending from the side of the circuit board provided with the lasers to the side provided with the graphite sheet.

14. The LiDAR according to claim 10, wherein the first direction extends along one end of the circuit board, and the second direction bends and extends from one side of the circuit board towards the thermal conduction bracket.

15. The LiDAR according to claim 14 wherein the second extension portions of the graphite sheets corresponding to the respective circuit boards are stacked.

16. The LiDAR according to claim 10, wherein the graphite sheet is a one-piece molded sheet.

17. The LiDAR according to claim 10, wherein the LiDAR thermal conduction device further comprises a plurality of connecting pillars disposed between the opto-mechanical bracket and the thermal conduction bracket, the circuit board further being provided with a plurality of perforations, the connecting pillars passing through the perforations and being fixed at both ends to the opto-mechanical bracket and the thermal conduction bracket, respectively.

19. A LiDAR, comprising:
an opto-mechanical bracket, connected to a heat dissipation component;
a thermal conduction bracket, spaced apart from the opto-mechanical bracket and in contact with the heat dissipation component;
a plurality of circuit boards, spaced apart and arranged between the opto-mechanical bracket and the thermal conduction bracket, each circuit board being configured to accommodate a plurality of lasers, the plurality of lasers being arranged in a straight line at intervals at one side of the circuit board; and
a graphite sheet comprising:
a contact portion, disposed on one side of the circuit board away from the lasers, and
two extension portions, extending from the contact portion, and respectively being in contact with the opto-mechanical bracket and the thermal conduction bracket.

20. The LiDAR according to claim 19, wherein a mounting area is provided near an edge of each the circuit board, to accommodate the plurality of lasers.
